(19) United States
(12) Patent Application Publication
(10) Pub. No.: US 2026/0362632 A1
(43) Pub. Date: Nov. 12, 2026

(54) FAN FRAME ELECTRICAL CONNECTION STRUCTURE

(71) Applicant: ASIA VITAL COMPONENTS CO., LTD., New Taipei City (TW)

(72) Inventors: Sung-Wei Sun, New Taipei City (TW); Feng Liu, New Taipei City (TW); Yong Xiang, New Taipei City (TW); Cun-Bao Lyu, New Taipei City (TW); Bing Liu, New Taipei City (TW)

(21) Appl. No.: 19/238,719

(22) Filed: Jun. 16, 2025

(30) Foreign Application Priority Data
May 9, 2025 (TW) 114117570

(51) Int. Cl. H05K 7/20

(52) U.S. Cl. CPC H05K 7/20172

(57) ABSTRACT

The fan frame electrical connection structure includes a fan frame, at least one flexible circuit board, and at least one external circuit board. The flexible circuit board is formed in the fan frame by way of over-molding. The flexible circuit board has an end located in the fan frame for electrically connecting to an internal circuit board and another end located outside the fan frame for electrically connected to the external circuit board, such that the internal circuit board and the external circuit board are electrically connected to each other via the flexible circuit board. With these arrangements, assembling labor, time, and cost for arranging, organizing, and welding fan conductors one by one can be saved, and the over-molded flexible circuit board is protected against undesired separation from the fan frame due to pulling by an external force.

This application claims the priority benefit of Taiwan patent application number 114117570 filed on May 9, 2025, the disclosure of which is hereby incorporated by reference in its entirety.

### FIELD OF THE INVENTION

The present invention relates to a fan, and more particularly, to a fan frame electrical connection structure that can save the assembling labor, time, and cost for arranging, organizing, and welding fan conductors one by one.

### BACKGROUND OF THE INVENTION

A fan is a very common device used in system heat dissipation and is frequently employed in an electronic apparatus, such as a server or a computer, to provide the function of forced heat dissipation. However, most conventional fans have a control circuit board that has to be outward extended and electrically connected to a motherboard of an external host for the purpose of signal transmission; and the control circuit board is electrically connected to the motherboard via a printed circuit board (PCB) with golden fingers. Conventionally, the PCB with golden fingers is fixed on the fan frame and the golden fingers are electrically connected and welded to conductors that are extended from the control circuit board in the fan frame. These conductors must first be arranged and organized in the fan frame, which is a highly difficult work. And, it is time and labor consuming to weld the conductors to the golden fingers one by one to largely increase the assembling cost.

It is therefore tried by the inventor to develop an improved fan frame electrical connection structure in order to overcome the problems of arranging and organizing conductors in the limited internal space of fan and welding the conductors to the golden fingers one by one.

### SUMMARY OF THE INVENTION

To effectively solve the above problems, a primary object of the present invention is to provide an improved fan frame electrical connection structure that utilizes a flexible circuit board to electrically connect an internal circuit board to an external circuit board, so as to efficiently utilize the limited internal space of a fan and save the assembling labor, time, and cost for arranging, organizing, and welding fan conductors one by one.

Another object of the present invention is to provide a fan frame electrical connection structure that includes a flexible circuit board that is not subjected to any risk of undesired separation from the fan frame due to pulling by an external force.

A further object of the present invention is to provide a fan frame electrical connection structure that reduces the space needed for arranging and organizing fan conductors and the saved space can be used to increase the blade pitch of the fan or reduce the fan frame volume.

To achieve the above and other objects, the fan frame electrically connection structure according to the present invention includes a fan frame, at least one flexible circuit board, and at least one external circuit board. The fan frame is internally provided with an internal circuit board, and has a fan frame surface formed thereon.

The flexible circuit board is formed in the fan frame through over-molding. The flexible circuit board has an end forming a first connection section and another end forming a second connection section. The flexible circuit board is electrically connected at the first connection section to the internal circuit board.

The external circuit board is provided on an outer side of the fan frame. The external circuit board is formed on one side with a first metal end section for electrically connected to the second connection section, such that the internal circuit board is electrically connected to the external circuit board via the flexible circuit board.

According to the fan frame electrical connection structure of the present invention, the flexible circuit board is over-molded in the fan frame for electrically connecting the internal circuit board to the external circuit board. With this arrangement, assembling labor, time, and cost for arranging, organizing, and welding fan conductors one by one can be effectively saved, and the flexible circuit board is protected against undesired separation from the fan frame due to pulling by an external force.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a fan frame electrical connection structure according to a first embodiment of the present invention;

FIG. 2 is an exploded perspective view of the fan frame electrical connection structure of FIG. 1;

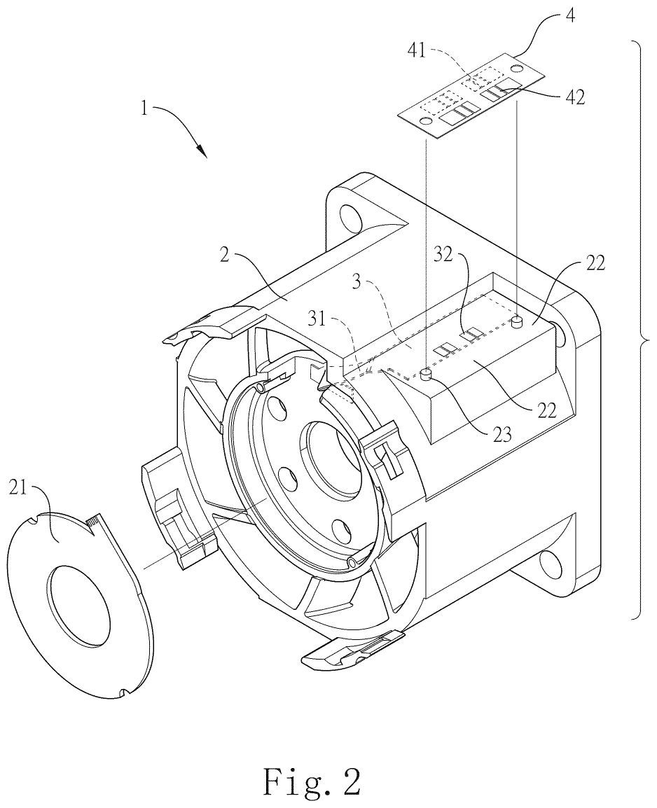

FIG. 3 is a cross sectional view of the fan frame electrical connection structure of FIG. 1; and

FIG. 4 is an assembled perspective view of a fan frame electrical connection structure according to a second embodiment of the present invention.

### DETAILED DESCRIPTION OF THE PREFERRED EMBODIMENTS

The present invention will now be described with some preferred embodiments thereof. For the purpose of easy to understand, elements that are the same in the preferred embodiments are denoted by the same reference numerals.

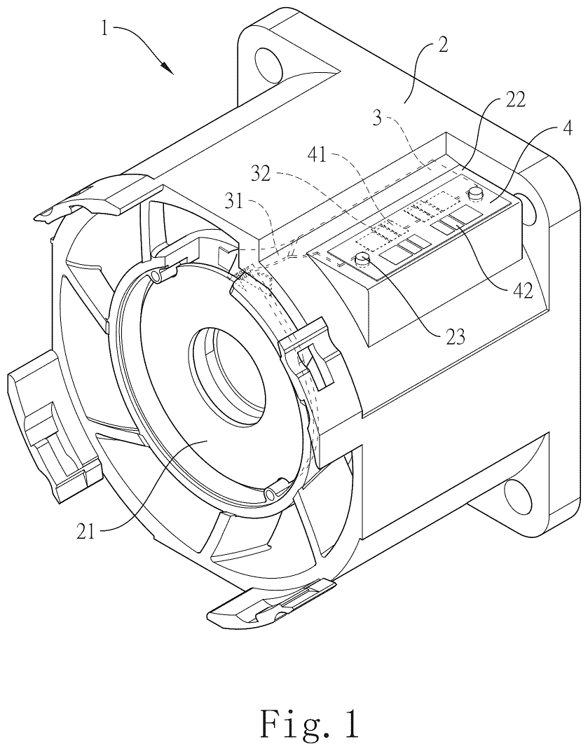

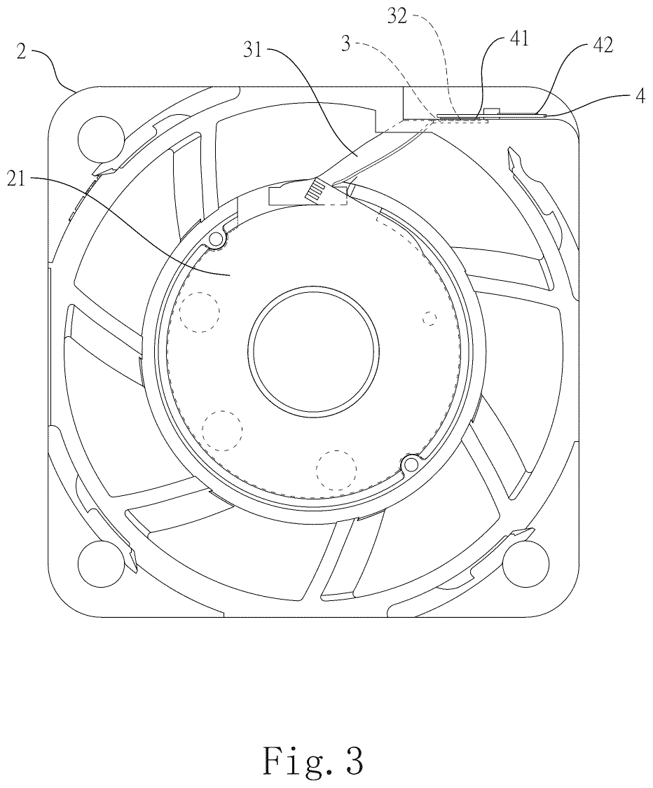

Please refer to FIG. 1, and 2, which are assembled and exploded perspective views, respectively, of a fan frame electrical connection structure 1 according to a first embodiment of the present invention; and to FIG. 3, which is a cross sectional view of the fan frame electrical connection structure of FIG. 1. As shown, the fan frame electrical connection structure 1 of the present invention includes a fan frame 2, at least one flexible circuit board 3, and at least one external circuit board 4.

The fan frame 2 is internally provided with at least one internal circuit board 21. The fan frame electrical connection structure 1 may be configured for accommodating one single motor or two motors. In the first embodiment, the illustrated fan frame 2 is configured for accommodating two motors therein, and the internal circuit board 21 is electrically connected to the two motors. However, it is understood the present invention is not necessarily limited to a dual-motor fan. The fan frame 2 is externally formed with a fan frame surface 22, on which at least one coupling section 23 is formed. The external circuit board is connected to and held in place on the outer side of the fan frame 2 via the coupling section 23.

The flexible circuit board 3 is formed in the fan frame 2 by way of over-molding and includes a first connection section 31 and a second connection section 32. The first connection section 31 is connected to the internal circuit board 21, while the second connection section 32 is exposed from the fan frame surface 22 of the fan frame 2.

The external circuit board 4 is located on the fan frame surface 22. The external circuit board 4 has one side defined as a first metal end section 41 and another opposite side defined as a second metal end section 42. The first metal end section 41 is a metal conductor formed through stamping, and is electrically connected to the second connection section 32. The second metal end section 42 is a metal conductor formed through stamping.

According to the fan frame electrical connection structure 1 of the present invention, the internal circuit board 21 and the external circuit board 4 are electrically connected to each other by connecting to two ends of the flexible circuit board 3. With this arrangement, assembling labor, time, and cost for arranging, organizing, and welding fan conductors one by one as required in the conventional fan can be saved. Further, since the flexible circuit board 3 is formed in the fan frame 2 through over-molding, the flexible circuit board 3 is protected against undesired separation from the fan frame 2 due to pulling by an external force. Meanwhile, since the external circuit board 4 is coupled with the flexible circuit board 3 over-molded in the fan frame 2, the external circuit board 4 is also protected against undesired displacement and separation from the fan frame 2 when it is electrically connected to an external device.

Further, with the advantage of the fan frame electrical connection structure 1 according to the present invention that it is not necessary to arrange and organize the conductors in the fan frame 2 one by one, a space inside the fan frame 2 that is initially required for arranging and organizing the conductors can be reduced. Since the space required to arrange and organize the conductors is reduced, there would be some space saved in the fan frame 2 of the same size. With the saved space in the fan frame 2, it is able to give the fan an increased fan blade pitch. Alternatively, with the saved space, the fan frame 2 can be designed to have a reduced volume, which in turn enables reduced flow field disturbance.

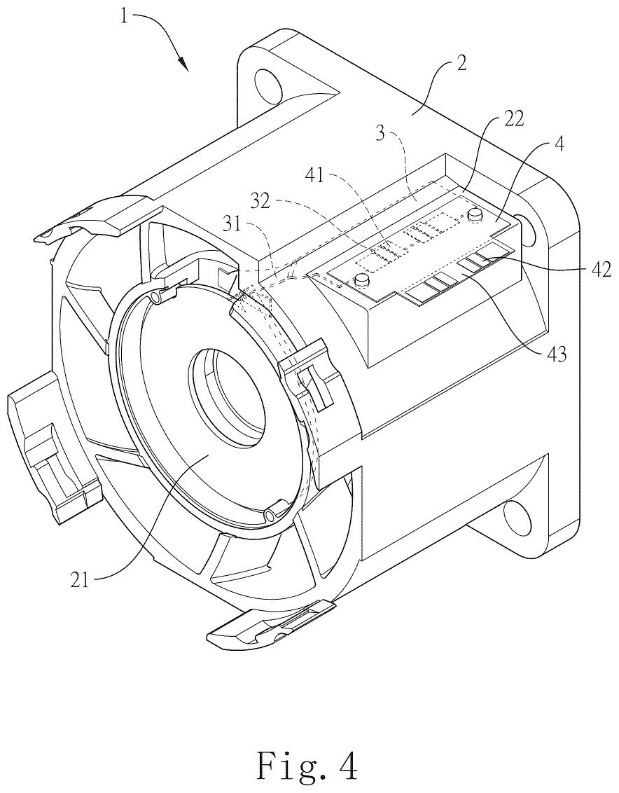

Please refer to FIG. 4, which is a perspective view of a fan frame electrical connection structure 1 according to a second embodiment of the present invention. In the second embodiment, the flexible circuit board 3 is also over-molded in the fan frame 2 and the external circuit board 4 is provided on the fan frame 2. The second embodiment is different from the first one in that the first metal end section 41 of the external circuit board 4 is connected to the second connection section 32, which is exposed from the fan frame 2, while the second metal end section 42 of the external circuit board 4 is provided on a docking section 43 of the external circuit board 4. The docking section 43 is located on one side of the external circuit board 4 opposite to the first metal end section 41 and forward protruded from the fan frame surface 22, such that the external circuit board 4 can be correspondingly connected to an external device via the docking section 43 and the second metal end section 42.

In conclusion, compared to the conventional fans, the present invention has the following advantages:
(1) Save the assembling labor, time, and cost initially required in the conventional fans to arrange, organize, and weld the conductors one by one;
(2) Effectively protect the flexible circuit board against undesired separation from the fan frame due to pulling by an external force;
(3) Enable increased fan blade pitch or reduced fan frame volume; and
(4) Effectively protect the external circuit board against undesired displacement and separation from the fan frame when the external circuit board is connected to an external device.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A fan frame electrical connection structure, comprising:
a fan frame being internally provided with an internal circuit board and having an external circuit board provided on an outer side thereof; and
at least one flexible circuit board being formed in the fan frame through over-molding; the flexible circuit board including a first connection section for electrically connecting to the internal circuit board and a second connection section for electrically connecting to the external circuit board, such that the internal circuit board and the external circuit board are electrically connected to each other via the flexible circuit board.

2. The fan frame electrical connection structure as claimed in claim 1, wherein the second connection section is exposed from a fan frame surface of the fan frame to be electrically connected to the external circuit board.

3. The fan frame electrical connection structure as claimed in claim 1, wherein the fan frame is formed with at least one coupling section, and the external circuit board being connected to and held in place on the outer side of the fan frame via the coupling section.

4. The fan frame electrical connection structure as claimed in claim 2, wherein the external circuit board is provided at one side with a first metal end section and at another opposite side with a second metal end section; and the second connection section being connected to the first metal end section.

5. The fan frame electrical connection structure as claimed in claim 4, wherein the external circuit board further includes a docking section forward protruded from the fan frame surface, and the second metal end section being located at the docking section.

6. The fan frame electrical connection structure as claimed in claim 5, wherein the first and the second metal end section are metal conductors formed through stamping.
